(19) United States
(12) Patent Application Publication
(10) Pub. No.: US 2011/0198116 A1
(43) Pub. Date: Aug. 18, 2011

(54) LAMINATE STRUCTURE

(75) Inventors: Junichi WATARI, Shiga (JP); Yoshihiro OKAWA, Shiga (JP)

(73) Assignee: KYOCERA CORPORATION, Kyoto (JP)

(21) Appl. No.: 13/029,643

(22) Filed: Feb. 17, 2011

(30) Foreign Application Priority Data
Feb. 18, 2010 (JP) 2010-033437

(51) Int. Cl. H05K 1/18; B32B 3/24; B32B 3/30

(52) U.S. Cl. 174/260; 428/140

(57) ABSTRACT

According to one embodiment of the present invention, a laminate structure comprises a laminate including a first substrate and a second substrate which is overlapped with the first substrate; and an exterior frame which surrounds a side surface of the laminate, and covers a region of both main surfaces of the laminate. Both of the first substrate and the second substrate have a through hole which is positioned at the region of the both main surfaces of the laminate. The exterior frame comprises a material which has lower elastic modulus than the laminate, and portions of the exterior frame extend into the through holes.

### CROSS REFERENCE TO RELATED APPLICATION

This application claims foreign priority based on Japanese Patent application No. 2010-033437 filed Feb. 18, 2010, the contents of which is incorporated herein by reference in its entirety.

### BACKGROUND OF THE INVENTION

1. Field of the Invention

The present invention relates to a laminate structure.

2. Description of the Related Art

Previously, a laminate structure has been used in various fields.

For example, using the laminate structure comprising circular ceramic substrates as a coin for amusement industry is under consideration.

In the field of radio-frequency identification (RFID) technology, a laminate structure is used for contact-free IC card as identification card (ID card), credit card, travel card and electrical money.

Coins for amusement industry and ID cards described above tend to be frequently subjected to large external forces when in use. For example, in the case of a coin for amusement industry, if the coin is inserted into an amusement machine, it drops in the amusement machine and is subjected to a large physical impact. For an ID card, when a user holds the ID card over a reader, the card may be strongly pressed against the reader and be subjected to a large pressure.

### SUMMARY OF THE INVENTION

According to one embodiment of the present invention, a laminate structure comprises a laminate including a first substrate and a second substrate which is overlapped with the first substrate; and an exterior frame which surrounds a side surface of the laminate, and covers a region of both main surfaces of the laminate. Both of the first substrate and the second substrate have a through hole which is positioned at the region of the both main surfaces of the laminate. The exterior frame comprises a material which has lower elastic modulus than the laminate, and portions of the exterior frame extend into the through holes.

### BRIEF DESCRIPTION OF THE DRAWINGS

FIG. 1A is a plan view of a coin according to an embodiment of the present invention, FIG. 1B is a cross-sectional view of the coin shown in FIG. 1A, FIG. 1C is a exploded view of the coin shown in FIG. 1A;

FIG. 2 illustrates an arrangement of projections, depressions, and through holes disposed on substrates being substantially symmetric with respect to a line;

FIGS. 3A and 3B illustrate an IC tag included in the coin, FIG. 3A is a plan view of the IC tag, FIG. 3B is a cross-sectional view of the IC tag;

FIG. 4 illustrates the IC tag included in the coin according to a variation;

FIGS. 5A to 5C illustrate how the coin is manufactured;

FIG. 6A is a plan view of a coin according to a second embodiment of the present invention, FIG. 6B is a cross-sectional view of the coin shown in FIG. 6A; and

FIG. 7 illustrates an arrangement of through holes of the coin according to the second embodiment of the present invention.

### DESCRIPTION OF THE REFERENCE SYMBOLS

2 laminate
2A first substrate
2B second substrate
3A projection on first substrate
3B projection on second substrate
4A opening on first substrate
4B opening on second substrate
5A depression on first substrate
5B depression on second substrate
7A through hole on first substrate
7B through hole on second substrate
8a main surface on second substrate
12a main surface on first substrate
8b another main surface on second substrate
12b another main surface on first substrate
9A first through hole group on first substrate
9B second through hole group on second substrate
10, 50 coin
14 antenna
16 sheet
18 IC chip
19 inner space
20 exterior frame
30 IC tag

### DESCRIPTION OF THE EXEMPLARY EMBODIMENTS

A laminate structure according to embodiments of the present invention is described below with reference to the drawings.

### First Embodiment

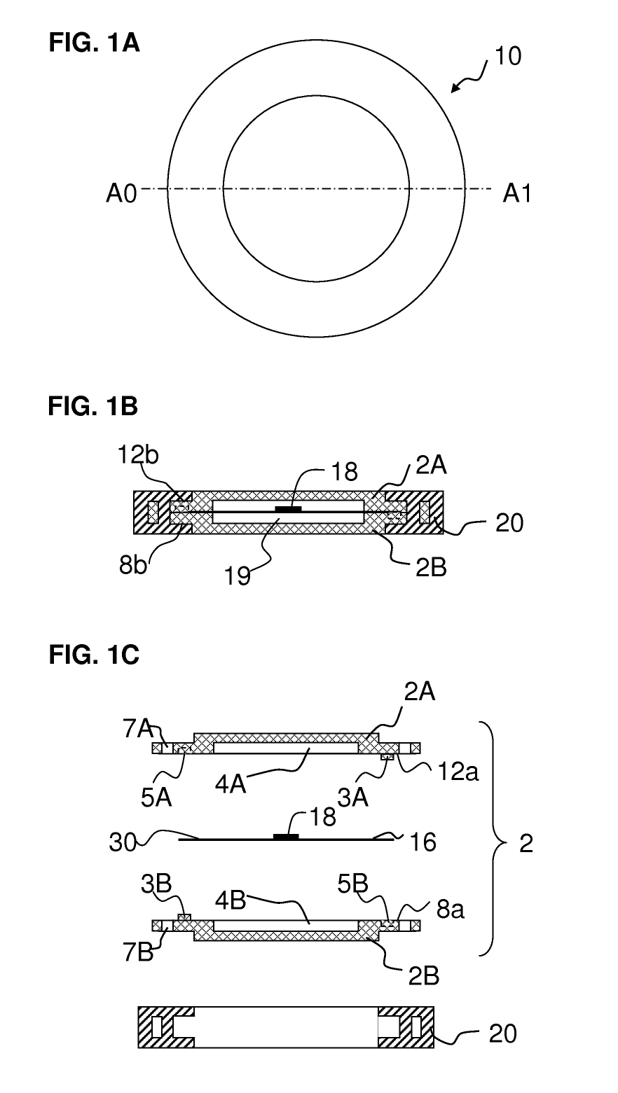

A laminate structure according to a first embodiment (hereinafter referred to as present embodiment) is described using a coin for amusement industry illustrated in FIGS. 1A to 1C as an example.

A coin 10 illustrated in FIGS. 1A to 1C includes a laminate 2, an exterior frame 20 covering the outer region of the laminate 2, and an IC tag 30 incorporated in the laminate 2.

The coin 10 serves as a token used in place of money in an amusement facility or other sites and also functions as an IC tag holder for holding the IC tag 30 therein. Various kinds of information on an amusement facility where the coin is used, the type of the coin, a history of uses of the coin can be stored in the IC tag 30, thus enabling the coin to be managed suitably for various uses and also allowing collection of information.

The laminate 2 includes a first substrate 2A including a main surface 12a having an opening 4A and a second substrate 2B including a main surface 8a having an opening 4B. The main surfaces of the first and second substrates 2A and 2B face each other such that the opening 4A and the opening 4B form an inner space 19 for accommodating an IC chip 18.

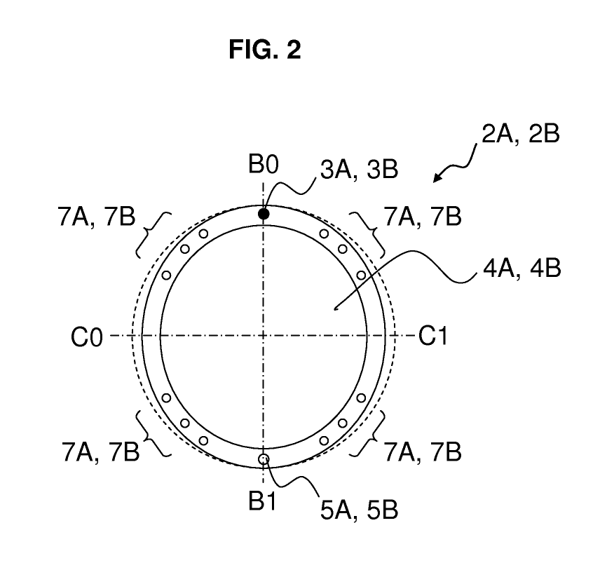

As illustrated in FIG. 2, the first and second substrates 2A and 2B included in the laminate 2 have substantially the same shape, and both are substantially symmetric with respect to a first imaginary line B0-B1. The first and second substrates 2A and 2B include, in their outer regions, specifically, in regions outside the openings 4A and 4B, projections 3A and 3B, depressions 5A and 5B corresponding to the projections 3B and 3A, and a plurality of through holes 7A and 7B penetrating through the thickness direction of the first and second substrates 2A and 2B, respectively.

The projection 3A and depression 5A are disposed at the main surface 12a in the outer region of the first substrate 2A. The projection 3B and depression 5B are disposed at the main surface 8a in the outer region of the second substrate 2B. The projection 3A and depression 5A are arranged on the first imaginary line B0-B1 of the first substrate 2A, and the projection 3B and depression 5B are arranged on the first imaginary line B0-B1 of the second substrate 2B. The first and second substrates 2A and 2B are fixed together by fitting the projection 3A into the depression 5B and fitting the projection 3B into the depression 5A. Accordingly, because the relative positional relationship between the first and second substrates 2A and 2B can be stabilized, even if a torsional external force is exerted in the planar direction of the main surface 12a and the main surface 8a, the first and second substrates 2A and 2B are relatively resistant to displacement.

The plurality of through holes 7A and 7B can have various shapes, including a substantially columnar shape. The plurality of (12 for the present embodiment) through holes are disposed in each of the first and second substrates 2A and 2B. The through holes 7A of the first substrate 2A and the corresponding through holes 7B of the second substrate 2B are in communication with each other.

The through holes 7A and 7B in the present embodiment are arranged in a positional relationship in which they are substantially symmetric with respect to a second imaginary line C0-C1, where the second imaginary line C0-C1 is an axis that is perpendicular to the line connecting the projection 3A and the depression 5A and the line connecting the projection 3B and the depression 5B in the first and second substrates 2A and 2B, that passes through the center of each of the first and second substrates 2A and 2B, and that is in parallel to the first and second substrates 2A and 2B. Additionally, as described above, the projection 3A and depression 5A and the projection 3B and depression 5B are arranged in a positional relationship in which they are substantially symmetric with respect to the second imaginary line C0-C1. Accordingly, even when substrates having substantially the same design are used as the first and second substrates 2A and 2B, their projections and depressions and their through holes are arranged at the same respective locations, respectively, and this can lead to improved productivity of the first and second substrates 2A and 2B. Note that, the design of the pattern of the opening 4A of the first substrate 2A and that of the opening 4B of the second substrate 2B may preferably be substantially the same. However, because the openings 4A and 4B have a sufficiently large size with respect to the projections, depressions, and through holes and its permissible amount of displacement is large, as long as the openings 4A and 4B overlap each other such that they form the inner space 19 for accommodating the IC chip, described below, the openings 4A and 4B may have different shapes and be in different locations.

The first substrate 2A and second substrate 2B in the present embodiment can include a ceramic sinter, for example, aluminum oxide, zirconium oxide, or a complex of aluminum oxide and zirconium oxide. Among ceramic sinters, aluminum oxide, zirconium oxide, and a complex of aluminum oxide and zirconium oxide have relatively high impact resistance and may preferably be used as a material of the laminate of the coin 10.

The above-described laminate 2 is provided with the exterior frame 20 attached thereto.

The exterior frame 20 is used to absorb impact on the coin 10 and includes a material that has a lower elastic modulus than that of the laminate 2. For example, in the case where the laminate 2 includes a ceramic material, as in the present embodiment, the exterior frame 20 includes a resin material, such as acrylonitrile butadiene styrene (ABS) copolymer resin. For a ceramic material and a metallic material, the elastic modulus of the material is measured by an ultrasonic pulse method; for a resin material, it is measured by a dynamic mechanical analysis.

The exterior frame 20 is attached to the laminate 2 so as to cover the side surfaces and the outer regions of both main surfaces of the laminate 2 and expose the center region of the laminate 2, the side surfaces and the outer regions being relatively receptive to impact. Therefore, even if the coin 10 is subjected to physical impact by, for example, being dropped or inserted into an amusement machine, the impact on the coin 10 is satisfactorily absorbed by the exterior frame 20, thus reducing the possibility of cracking of the coin and chipping in the edges of the coin and additionally, having relatively smaller physical impact reaching the laminate 2 and, by extension, the IC chip 18 accommodated in the laminate 2.

Moreover, the exterior frame 20 extends such that the through holes 7A and 7B of the first and second substrates 2A and 2B are filled with portions of the exterior frame 20. Of the exterior frame 20, the portions extending within the through holes 7A and the corresponding portions extending within the through holes 7B are connected together. Accordingly, the strength of connection between the part of the exterior frame 20 adjacent to another main surface 12b and the part of the exterior frame 20 adjacent to another main surface 8b can be relatively increased. Thus, even if an external force parallel to the laminate 2 or that for separating the exterior frame 20 from the laminate 2 is exerted on the exterior frame 20, the portions of the exterior frame 20 in the through holes 7A and 7B serve as an anchor and the exterior frame 20 can be satisfactorily attached to the laminate 2. As a result, if a pattern or a character is present in the surface of the coin 10, that is, from the surface of the central region of the laminate 2 to the surface of the exterior frame 20, displacement of the pattern or character can be reduced, and high recognizability of the pattern or text and a good appearance of the coin can be maintained.

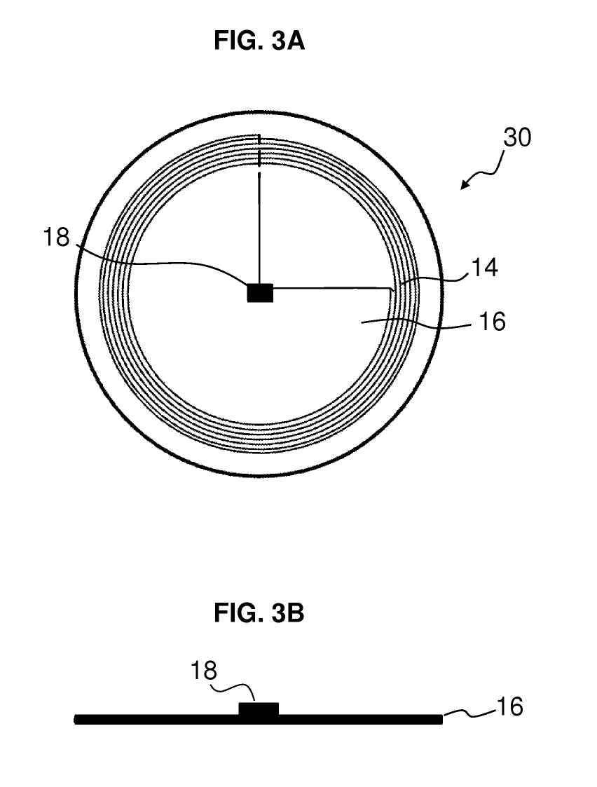

As illustrated in FIGS. 3A and 3B, the IC tag 30 incorporated in the laminate 2 includes a sheet 16, the IC chip 18 mounted on the sheet 16, and an antenna 14 disposed on the sheet 16. The IC tag 30 is sandwiched between the first substrate 2A and the second substrate 2B.

The sheet 16 is used to support the IC chip 18 and the antenna 14 and can include a resin material, such as polyethylene terephthalate (PET). The sheet 16 has a sandwiched region directly sandwiched between the first substrate 2A and the second substrate 2B and a non-sandwiched region which is arranged within the inner space 19 and is not in direct contact with the substrates 2A and 2B. For the present embodiment, the antenna 14 is arranged in the sandwiched region, whereas the IC chip 18 is arranged in the non-sandwiched region.

The antenna 14 disposed on the sheet 16 has the function of receiving a radio signal from the outside or transmitting a radio signal to the outside and is connected to the IC chip 18.

The antenna 14 can include electrical wiring including a metallic material whose principal component can be copper, gold, silver, aluminum, or palladium, for example. The electrical wiring is spiral at predetermined intervals in the outer region of the sheet 16.

Typical antenna systems can be classified into the electromagnetic induction type, in which energy and signals are exchanged with an external receiver-transmitter having a flux-coupled antenna coil, and the radio type, in which radio waves are exchanged with an external receiver-transmitter and energy and signals are transmitted or received. The antenna 14 according to the present embodiment uses the electromagnetic induction type. As described above, the antenna 14 is sandwiched between the first and second substrates 2A and 2B, which include a ceramic material. As a result, a high dielectric constant of the ceramic material allows satisfactory passage of a radio wave, thus enabling a radio wave to be satisfactorily received from and transmitted to an external radio-wave receiver-transmitter, for example.

If the antenna 14 uses the radio wave type, it has a wavelength shortening effect on a radio wave to be received by the antenna 14 because the antenna 14 is sandwiched between the first and second substrates 2A and 2B, both of which include a ceramic material having a high dielectric constant. As a result, the electrical wiring of the antenna 14 can be shortened, and the antenna 14 can be miniaturized.

The IC chip 18 connected to the antenna 14 includes a memory, e.g., an electrically erasable programmable read-only memory (EEPROM), an integrated circuit, and a modulator on a semiconductor substrate including, for example, silicon. The integrated circuit reads information from and writes information to the memory. The modulator can convert a radio wave received through the antenna 14 into an electrical signal and can convert an electrical signal into a radio wave transmitted through the antenna 14. The memory can store various kinds of information, such as information on an amusement facility at which the coin is used, the type of the coin, and a history of uses of the coin, as previously described. The stored information can be updated as needed by driving of the integrated circuit in response to a signal externally received from the antenna through the modulator and can be transmitted as a radio wave to the outside through the modulator and the antenna 14.

The IC chip 18 is arranged in the inner space 19, which is formed by the opening 4A of the first substrate 2A and the opening 4B of the second substrate 2B facing each other, and the IC chip 18 is neither directly bonded to nor in contact with the first and second substrates 2A and 2B. Accordingly, even if the coin 10 and, by extension, the laminate 2 are subjected to physical impact by, for example, being dropped or inserted into an amusement machine, because the energy of the impact is absorbed as energy of vibrating the sheet 16 in the inner space 19, the physical impact reaching the IC chip 18 through the sheet 16 is relatively small.

The IC chip 18 is mounted on the sheet 16 by being connected to the electrical wiring of the antenna 14 through a binder, such as a solder bump, bonding wire, or conductive resin.

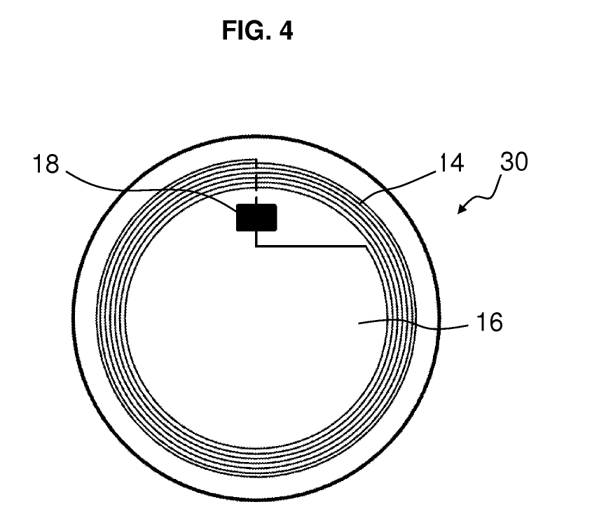

To have a relatively high transmission and reception sensitivity to a radio wave, the IC chip 18 may preferably be arranged at a location remote from the center of the sheet 16, as illustrated in FIG. 4. Specifically, the IC chip 18 may be arranged in the vicinity of the antenna 14, that is, in the outer region of the inner space 19, so as not to be in contact with the wall of each of the openings 4A and 4B. With this configuration, the IC chip 18 is arranged at a location remote from a region on which an electromagnetic wave formed by the antenna 14 is relatively focused (the center of the sheet 16), thus reducing attenuation of an electromagnetic wave caused by the IC chip 18 and achieving relatively high transmission and reception sensitivity to a radio wave.

Next, one example of a method of manufacturing the above-described coin 10 is described.

(1) First, the first and second substrates 2A and 2B are prepared.

The first and second substrates 2A and 2B are produced by known uniaxial pressing, for example. Specifically, a superhard die for use in pressing (press die) having a shape corresponding to a desired shape of the first and second substrates 2A and 2B is filled with ceramic powder in which a ceramic raw material and a binder are mixed, pulverized, and granulated, they are pressed at ordinary temperature, and a pressed compact having the desired shape is produced. The pressed compact is co-fired at approximately 1400 to 1700° C. for approximately 1 to 10 hours, and the first and second substrates 2A and 2B are obtained.

For the first and second substrates 2A and 2B obtainable by uniaxial pressing, shrinkage occurring in ceramic co-firing can be restricted by control of packing density of ceramic particles in the press die or temperature distribution at co-firing, thus enabling each substrate to be substantially symmetric with respect to the single imaginary line B0-B1 with relatively high precision, as illustrated in FIG. 2. If it is difficult to control packing density of ceramic particles in the press die or temperature distribution at co-firing, the use of a press die formed in consideration of shrinkage in ceramic co-firing enables a substrate obtained after co-firing to have a desired shape, such as a shape being substantially symmetric with respect to a line or a near perfect circle, with relatively high precision.

In the case of uniaxial pressing, burrs are likely to occur in the edges of the first and second substrates 2A and 2B. Therefore, a design in which the edges are chamfered in advance may be preferable. The first and second substrates 2A and 2B after sintering may be subjected to barrel polishing as needed to remove burrs of the ends of the sinter.

(2) Next, the IC tag is prepared.

A PET resin sheet is prepared, conductive wiring including, for example, copper is formed on the resin sheet by a known photolithography method to form the antenna 14, the IC chip 18 produced by a known semiconductor manufacturing technique is bonded to the conductive wiring by the use of conductive epoxy adhesive, and the IC tag 30 is produced.

(3) The first substrate, second substrate, and IC tag are assembled into a laminate.

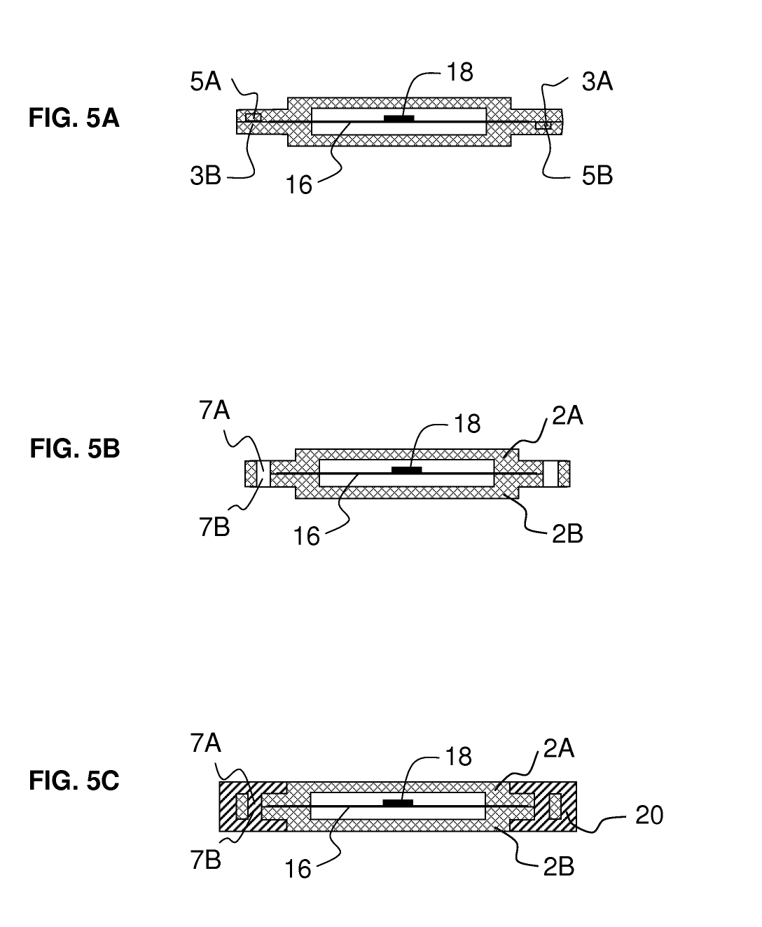

The IC tag 30 is sandwiched between the first and second substrates 2A and 2B by fitting the projections into the corresponding depressions of the first and second substrates 2A and 2B with the IC tag 30 interposed therebetween. The projection 3A and depression 5A are disposed at the main surface 12a in the outer region of the first substrate 2A and the projection 3B and depression 5B are disposed at the main surface 8a in the outer region of the second substrate 2B. At this time, they are assembled such that the projection 3A is fitted into the depression 5B and the projection 3B is fitted into the depression 5A, as illustrated in FIG. 5A. In this way, for the present embodiment, because engagement of a depression and a projection is employed in assembly, alignment in assembly can be relatively easy.

The IC tag may be bonded by application of heat-resistant adhesive, such as epoxy resin, to outer regions of the first and second substrates 2A and 2B, specifically, to regions of the first and second substrates 2A and 2B that face each other outside the openings 4A and 4B. In this case, the projections and depressions are not necessarily required.

As described above, the first and second substrates 2A and 2B have substantially the same shape and are substantially symmetric with respect to a line, and the projection 3A and depression 5A and the projection 3B and depression 5B of the substrates are arranged on the first imaginary line B0-B1 of the substrates. In addition, the first and second substrates 2A and 2B have the plurality of through holes 7A and 7B, respectively, and the through holes 7A and 7B are arranged in a positional relationship in which they are substantially symmetric with respect to the second imaginary line C0-C1. Accordingly, alignment of the first substrate 2A and the second substrate 2B can be easy. For example, the through holes 7A and the corresponding through holes 7B are in communication with each other at substantially the same locations with high accuracy, as illustrated in FIG. 5B.

(4) The exterior frame is formed, and the manufacturing of coin 10 is completed.

The exterior frame 20 is formed by a known injection molding method. The obtained laminate 2 is arranged within a die of an injection molding machine, an outer region of the laminate 2 is exposed, molten resin of ABS copolymer resin is injected into the outer region, the molten resin is fitted to both surfaces and side surfaces of the laminate 2 in the outer region and to the inside of the through holes 7A and 7B in communication with each other, as illustrated in FIG. 5C, the molten resin is hardened, and the exterior frame 20 is produced.

Here, because the through holes 7A and 7B are in communication with each other at substantially the same locations with high accuracy, as illustrated in FIG. 5B, in injection molding, ABS resin can be satisfactorily injected into the through holes 7A and 7B without many voids occurring in the ABS resin. Consequently, the strength of connection between the laminate 2 and the exterior frame 20 can be increased, the exterior frame 20 can be satisfactorily attached to the laminate 2, and the occurrence of problems, such as rotation of the laminate 2 with respect to the exterior frame 20, can be reduced.

The exterior frame 20 and the exposed portion of the laminate 2 may be decorated with a pattern or a character by printing or flame gunning. The decoration may be performed simultaneously in an injection molding step.

Through the above-described process, the manufacturing of coin 10 is completed.

### Second Embodiment

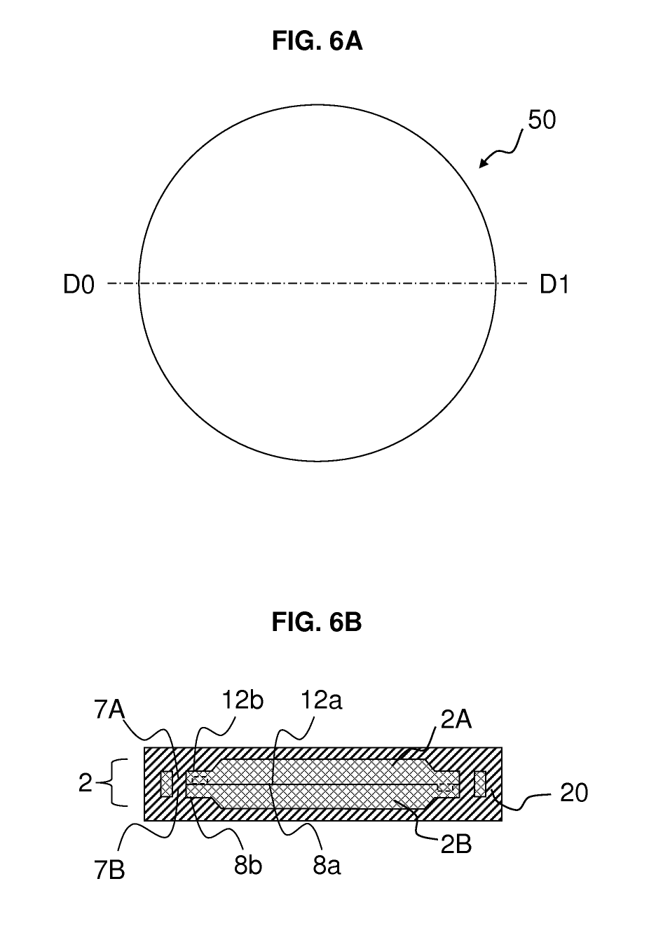

FIGS. 6A and 6B illustrate a laminate structure according to a second embodiment of the present invention and are diagrams of a coin 50 having a different form from the coin 10 illustrated in FIGS. 1A to 1C. In FIGS. 6A and 6B, the same reference numerals are used as in FIGS. 1A to 1C for similar elements, and a detailed description thereof is omitted.

The coin 50 according to the second embodiment is different from the coin 10 according to the first embodiment in that the coin 50 includes no openings in the main surface 12a and the main surface 8a, the main surface 12a and the main surface 8a are substantially planar, and the exterior frame 20 is molded collectively so as to cover the whole of the laminate 2. With this configuration, although the outward appearance and the touch are similar to those of a traditionally used resin coin for amusement industry, the IC tag 30 can be held in the laminate 2 while relatively high impact resistance is achieved, and the use of a ceramic material in the laminate 2 can lead to solid-looking and can show a quality appearance as a coin for amusement industry.

To increase the strength of connection between the laminate 2 and the exterior frame 20, as illustrated in FIG. 6B, it is effective to provide at least one step to each of the main surface 12b of the first substrate 2A and the main surface 8b of the second substrate 2B, the main surfaces 12b and 8b being in contact with the exterior frame 20. The anchoring effects of the shape of the step can improve the strength of connection between the substrates and the exterior frame.

To improve the strength of connection between the substrates and the exterior frame, other than providing a simple step, as described above, molding or processing many spindle-shaped depressions on each of the main surface 12b and the main surface 8b is also effective.

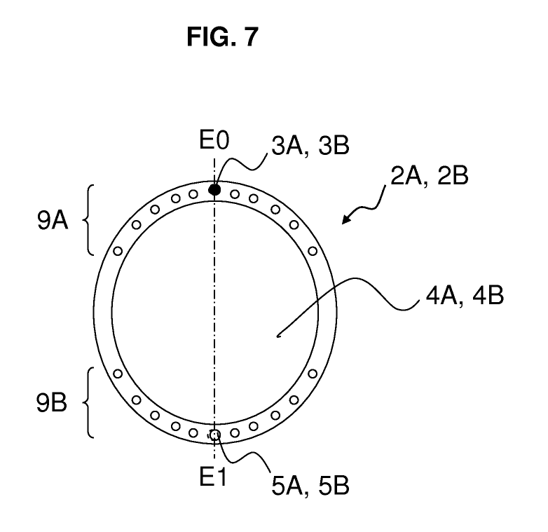

The coin 50 is also different from the coin 10 according to the first embodiment in the arrangement of through holes and density thereof in the arrangement. As illustrated in FIG. 7, the plurality of through holes according to the present embodiment are classified into a first through hole group 9A corresponding to the projections 3A and 3B and a second through hole group 9B corresponding to the depressions 5A and 5B, each group consisting of three or more through holes. The density of through holes in the arrangement in regions adjacent to the projections 3A and 3B and depressions 5A and 5B is higher than that in regions remote from the projections 3A and 3B and depressions 5A and 5B.

As described above, for a substrate molded by uniaxial pressing, being substantially symmetric with respect to a line, and shrinking toward the direction of an imaginary line E0-E1, weight balance of the substrate can be achieved by disposing the projection 3A and depression 5A and the projection 3B and depression 5B on the imaginary line and arranging more through holes in a region adjacent to the projections 3A and 3B and the depressions 5A and 5B.

To achieve weight balance as the coin, for the coin 10, it is also effective to provide a balance member to the laminate 2 or the exterior frame 20. The balance member can reduce deviation of the weight profile obtained by combining a weight profile of the laminate 2 and that of the exterior frame 20 together.

The present invention is not limited to the above-described first and second embodiments. Various improvements and changes can be made without departing from the scope of the present invention.

For example, for the present embodiment, the first and second substrates 2A and 2B of the laminate 2 include a ceramic material. However, they may include a metal or thermoplastic resin. If the first and second substrates 2A and 2B include a metal and, as in the case of the above-described embodiments, if the antenna is sandwiched between the first and second substrates, in order to prevent the metal and antenna from being in contact with each other, it is necessary to insulate the antenna from the substrates by, for example, forming an insulating layer on the main surface of one of the substrates that is adjacent to the antenna or covering the antenna with an insulative protective film.

For the above-described embodiments, the first and second substrates have substantially the same shape and are substantially symmetric with respect to a line. However, they may have different shapes and may be asymmetric.

The exterior frame 20 may include a metal, such as aluminum. If the exterior frame 20 includes aluminum, the exchange of radio waves between the IC tag 30 and an external receiver-transmitter is blocked by the metal. Accordingly, the exchange of radio waves from the side surfaces of the coin 10 is not allowed, and the exchange of radio waves only from the main surfaces of the coin 10 is allowed. As a result, a crossed line occurring in radio waves between the coins 10 can be reduced, and proper exchange of radio waves can be achieved.

For the present embodiment, each of the first and second substrates 2A and 2B includes both a projection and a depression. However, one of the substrates 2A and 2B may include only a projection, and the other may include only a depression. Any number of projections and any number of depressions may be used.

For the above-described embodiments, the through holes 7A and 7B are in communication with each other at substantially the same locations. However, the thorough holes may be in communication with each other at different locations slightly displaced. Alternatively, the through holes may not be in communication with each other.

For the present embodiment, the IC tag 30 is incorporated in the laminate 2. However, the IC tag 30 is not necessarily required.

For the present embodiment, a coin for amusement industry is described as one example. However, applications of a laminate structure according to the present invention are not particularly limited. Examples of the applications can include a label for use in management of movement in a delivery route for an item, a tag for use in traceability of an item in a distribution process, a sensor holder used in a sensor network that aims to obtain meaningful data from sensors at various sites.

With the embodiments of the present invention, a laminate structure includes a laminate and an exterior frame, the exterior frame surrounds a side surface of the laminate and extends in at least an outer region of both main surfaces of the laminate, and the exterior frame includes a material having an elastic modulus lower than that of the laminate. Accordingly, impact on the laminate structure can be satisfactorily absorbed by the exterior frame, the impact conveyed to the laminate can be relieved, and the occurrence of chipping and breakage in the laminate structure can be satisfactorily reduced.

Furthermore, because the laminate has a through hole penetrating through a substrate and the through hole of the laminate is filled with part of the exterior frame, even if a transversal force is exerted on the exterior frame, the part of the exterior frame in the through hole serves as an anchor. Accordingly, separation of the exterior frame from the laminate can be satisfactorily reduced.

While various embodiments of the present invention have been described above, it should be understood that they have been presented by way of example only, and not of limitation. Likewise, the above figures may depict exemplary configurations for the invention, which is done to aid in understanding the features and functionality that can be included in the invention. The invention is not restricted to the illustrated architectures or configurations, but can be implemented using a variety of alternative architectures or configurations. Additionally, although the invention is described above in terms of various exemplary embodiments and implementations, it should be understood that the various features and functionality described in one or more of the individual embodiments are not limited in their applicability to the particular embodiment with which they are described, but instead can be applied, alone or in some combination, to one or more of the other embodiments of the invention, whether or not such embodiments are described and whether or not such features are presented as being a part of a described embodiment. Thus the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as means “including, without limitation” or the like; the term “example” is used to provide exemplary instances of the item in discussion, not an exhaustive or limiting list thereof; and adjectives such as “traditional,” “known” and terms of similar meaning should not be construed as limiting the item described to a given time period or to an item available as of a given time, but instead should be read to encompass conventional, traditional, normal, or standard technologies that may be available or known now or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should be not be read as requiring mutual exclusivity among that group, but rather should also be read as “and/or” unless expressly stated otherwise. Furthermore, although items, elements or components of the disclosure may be described or claimed in the singular, the plural is contemplated to be within the scope thereof unless limitation to the singular is explicitly stated. The presence of broadening words and phrases such as “one or more,” “at least,” or other like phrases in some instances shall not be read to mean that the narrower case is intended or required in instances where such broadening phrases may be absent.

1. A laminate structure comprising:
a laminate including a first substrate and a second substrate which is overlapped with the first substrate; and
an exterior frame which surrounds a side surface of the laminate, and covers a region of both main surfaces of the laminate;
wherein both the first substrate and the second substrate have a through hole which is positioned at the region of the both main surfaces of the laminate; and
the exterior frame comprises a material which has lower elastic modulus than the laminate, and portions of the exterior frame extend into the through holes.

2. The laminate structure according to claim 1, wherein
the through hole of the first substrate is overlapped with at least a part of the through hole of the second substrate; and
the portion of the exterior frame extended into the through hole of the first substrate and the portion of the exterior frame extended into the through hole of the second substrate connect to each other.

3. The laminate structure according to claim 1, wherein
the first substrate has a main surface, and the second substrate has a main surface which faces the main surface of the first substrate,
the first substrate has projections at the main surface thereof;
the second substrate has depressions at the main surface thereof; and
the projections fit into the depressions.

4. The laminate structure according to claim 1, wherein
the first substrate has a main surface, and the second substrate has a main surface which faces the main surface of the first substrate,
the first substrate has a projection and a depression at the main surface thereof;
the second substrate has a projection and a depression at the main surface thereof; and
the projection of the first substrate fits into the depression of the second substrate, and the projection of the second substrate fits into the depression of the first substrate.

5. The laminate structure according to claim 4, wherein
the first substrate and the second substrate have substantially the same configuration and are line-symmetric with respect to a first and a second imaginary lines, respectively, and
the projection and the depression of each of the first substrate and the second substrate are arranged on each the first and the second imaginary line.

6. The laminate structure according to claim 4, wherein
each of the first substrate and the second substrate has through holes,
the through holes on the first substrate are arranged symmetrically with respect to a first hypothetical line which is perpendicular to a first line connecting the projection and the depression of the first substrate, is through a center of the first substrate, and is parallel to the first substrate, and
the through holes on the second substrate are arranged symmetrically with respect to a second hypothetical line which is perpendicular to a second line connecting the projection and the depression of the second substrate, is through a center of the second substrate, and is parallel to the second substrate.

7. The laminate structure according to claim 6, wherein
the through holes are classified into a first and a second through hole groups, and
the first through hole group includes three or more through holes near the projection of the first and the second substrate,
the second through hole group includes three or more through holes near the depression of the first and the second substrate,
in each of the first and the second substrate, through holes of the first and second through hole group has a first density at a first region and a second density higher than the first density at a second region nearer to the projection than the first region, and
through holes of the first and second through hole group have a third density at a third region and a fourth density higher than the third density at a fourth region nearer to the depression than the third region.

8. The laminate structure according to claim 1, wherein
the laminate includes a step at the region covered by the exterior frame.

9. The laminate structure according to claim 1, wherein
the first substrate and the second substrate comprise ceramics.

10. The laminate structure according to claim 1, further comprising:
a balance member reducing deviation of an entire weight profile which is obtained by combining a weight profile of the laminate to a weight profile of the exterior frame, the balance member being attached onto the laminate or the exterior frame.

11. The laminate structure according to claim 1, wherein
there is an inner space between the first substrate and the second substrate.

12. The laminate structure according to claim 11, comprising an IC chip inside the inner space.

13. The laminate structure according to claim 12, further comprising a sheet interposed between the first substrate and the second substrate, wherein the sheet has a portion which is in the inner space and is apart from the first substrate and the second substrate, and the IC chip is mounted within the portion of the sheet.
